(19) United States
(12) Patent Application Publication
(10) Pub. No.: US 2010/0322002 A1
(43) Pub. Date: Dec. 23, 2010

(54) EEPROM DEVICE

(75) Inventor: Masahiko Shinozawa, Miyazaki (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI SEMICONDUCTOR CO., LTD., Tokyo (JP)

(21) Appl. No.: 12/788,580

(22) Filed: May 27, 2010

(30) Foreign Application Priority Data
Jun. 19, 2009 (JP) 2009-146018

(51) Int. Cl. G11C 16/04

(52) U.S. Cl. 365/185.05; 365/185.02

(57) ABSTRACT

An EEPROM device which prevents disturbance phenomena when writing data on a memory cell. The device includes an on/off switch element for selectively connecting between an individual source line and a common source line in response to a control signal supplied via a control terminal.

### BACKGROUND OF THE INVENTION

1. Field of the Invention

The present invention relates to EEPROM devices which have a plurality of memory cells disposed in a matrix.

2. Description of the Related Art

There are EEPROM (Electrically Erasable Programmable ROM) devices known as nonvolatile semiconductor memories which allow for electrically writing and erasing data thereon. The EEPROM device has a plurality of memory cells which each have a control gate and a floating gate and are disposed in a matrix with rows and columns. In general, each row is provided with a word line that is connected to the control gate of each memory cell disposed in the corresponding respective row. On the other hand, each column is provided with a bit line that is connected to the drain of each memory cell disposed in the corresponding respective column. Furthermore, each memory block is provided with a source line that is connected to the source of each of the plurality of memory cells which are included in the corresponding respective memory block. These word lines, bit lines, and source lines are supplied with an appropriate voltage, thereby allowing data to be selectively written or erased on at least one memory cell. Examples of such a nonvolatile semiconductor storage device is disclosed in Japanese Patent Kokai No. 2001-184878 (Patent Document 1) and Japanese Patent Kokai No. H4-123471 (Patent Document 2).

### SUMMARY OF THE INVENTION

There are some EEPROM devices which are provided with common source lines for supplying a common voltage to each source line in order to facilitate control of the devices. The common source line is brought into a so-called floating state to write data on a memory cell or withdraw electrons which have been accumulated on the memory cell. With electrons withdrawn therefrom, the memory cell has a reduced threshold voltage and is turned on. Then, the memory cell will have an increased source potential caused by a high potential that has been applied to the drain of the cell to withdraw electrons therefrom, resulting in an increase in the potential of the common source line. That is, this will cause a rise in the potential of the common source line that should essentially remain in the floating state and an increase in the potential of the memory cell source, connected to the common source line, which is primarily to keep the threshold voltage of the memory cell at a high level. This leads to a depletion layer appearing in the junction between the source and the substrate of the memory cell, and raises the potential of the drain region when the depletion layer reaches the drain region. This results in electrons being withdrawn from the floating gate electrode via a tunnel window region of the memory cell, while the memory cell is reduced in threshold voltage and turned on. This causes the so-called disturbance phenomenon in which data is written on an originally unintended memory cell.

According to an aspect of the present invention, there is provided an EEPROM device which prevents disturbance phenomena when writing data on a memory cell.

According to embodiments, there is provided an EEPROM device which includes a plurality of memory cell FETs, an individual source line and a bit line for supplying a potential difference between the source and the drain of the memory cell FET, a gate line connected to the gate of the memory cell FET, and a byte select line for supplying a write/erase potential to the gate line. The EEPROM device includes an on/off switch element for selectively connecting between the individual source line and the common source line in response to a control signal supplied via its control terminal.

According to embodiments, there is provided an EEPROM device which includes a plurality of memory cell blocks which each include a plurality of memory cell FETs and are disposed in a matrix, and a supply source line for supplying a source potential to the individual source line of each of the memory cell blocks. The EEPROM device includes an on/off switch element for selectively connecting between the individual source line and the supply source line in response to a control signal supplied via its control terminal.

The EEPROM device can prevent disturbance phenomena when writing data onto the memory cells.

### BRIEF DESCRIPTION OF THE DRAWINGS

FIG. 1 is a circuit diagram illustrating an EEPROM device according to a first embodiment;

FIG. 2 is a block diagram illustrating an EEPROM device;

FIG. 3 is a layout diagram illustrating an example layout of an EEPROM device;

FIG. 4 is a table showing an example of setting a potential to erase data;

FIG. 5 is a table showing an example of setting a potential to write data; and

FIG. 6 is a circuit diagram illustrating an EEPROM device according to a second embodiment.

### DETAILED DESCRIPTION OF THE INVENTION

The present invention will now be described below in more detail with reference to the accompanying drawings in accordance with the embodiments.

### First Embodiment

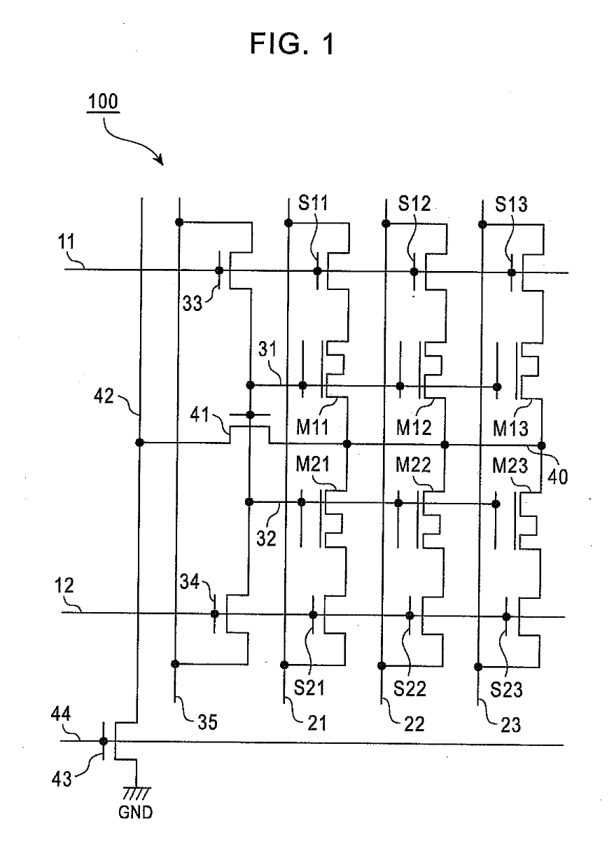

FIG. 1 is a circuit diagram illustrating an EEPROM device 100 according to the present embodiment. The EEPROM device 100 is a semiconductor memory, such as an EEPROM, which allows for electrically writing and erasing data thereon. The EEPROM device 100 has memory cells M11 to M23 which are formed in a matrix with rows and columns on the surface of a semiconductor substrate (not shown) such as a silicon substrate. Note that FIG. 1 shows only one of the plurality of memory cell blocks that constitute the EEPROM device 100.

Each of the memory cells M11 to M23 is a so-called nonvolatile memory cell FET (Field Effect Transistor) element which includes a floating gate and a control gate. The drain of each of the memory cells M11 to M23 is connected in pairs with each of switch elements S11 to S23 or FET elements, respectively. For example, the drain of the memory cell M11 is connected with the source of the switch element S11.

The gate of each of the switch elements S11 to S13 is connected to a word line 11 which extends in the row direction. When the word line 11 is supplied with a high potential Vpp (hereinafter simply referred to as the Vpp), each of the switch elements S11 to S13 is turned on. On the other hand, the gate of each of the switch elements S21 to S23 is connected to a word line 12 which extends in the row direction. When the word line 12 is supplied with the Vpp, each of the switch elements S21 to S23 is turned on.

The drain of each of the switch elements S11 and S21 is connected to a bit line 21 which extends in the column direction, while the drain of each of the switch elements S12 and S22 is connected to a bit line 22 which extends in the column direction. Further, the drain of each of the switch elements S13 and S23 is connected to a bit line 23 which extends in the column direction. For example, when the word line 11 is supplied with the Vpp resulting in the switch element S11 to be turned on, the potential applied to the bit line 21 is applied to the drain of the memory cell M11.

The gate of each of the memory cells M11 to M13 is connected to a gate line 31 which extends in the row direction, and the gate of each of the memory cells M21 to M23 is connected to a gate line 32 which extends in the row direction. The gate line 31 is connected to a byte select line 35 via a byte select element 33 or an FET element. The gate line 32 is connected to the byte select line 35 via a byte select element 34 or an FET element.

The gate of the byte select element 33 is connected to the word line 11, and when the word line 11 is supplied with the Vpp, the byte select element 33 is turned on. The gate of the byte select element 34 is connected to the word line 12, so that the byte select element 34 is turned on when the word line 12 is supplied with the Vpp. When the byte select element 33 or 34 is turned on, the write or erase potential applied to the byte select line 35 is applied to the gate of each of the memory cells M11 to M23, causing each of the memory cells M11 to M23 to be turned on.

The Memory cells M11 to M13 and the memory cells M21 to M23 are disposed in mutually adjacent rows to oppose each other. The source of each of the memory cells M11 to M23 is connected to an individual source line (hereinafter simply referred to as the source line) 40. The source line 40 is connected to a common source line 42 via an on/off switch element (hereinafter referred to as the switching element 41). More specifically, the drain of the switching element 41 or an FET element is connected to one end of the source line 40, with the source connected to the common source line 42. The gate serving as a control terminal for providing on/off switching control is connected to the byte select line 35 via the byte select elements 33 and 34.

One end of the common source line 42 is grounded via a common source line control element 43. More specifically, the source of the common source line control element 43 or an FET element is connected to the GND potential (the ground potential, hereinafter simply referred to as the GND), with the drain connected to one end of the common source line 42. The gate is connected to a common source line control line 44 (hereinafter simply referred to as the source control line 44) which extends in the row direction.

To erase data, that is, to inject electrons into the floating gate of each of the memory cells M11 to M23, the common source line control element 43 is switched to an ON state by applying, to the byte select line 35, the Vpp serving also as a control signal to turn on or off the switching element 41 as well as a high potential Vcc (lower than the Vpp, hereinafter simply referred to as the Vcc) to the source control line 44. At the same time, the Vpp is applied to the word line 11 or 12 to turn on the byte select element 33 or 34 to thereby apply the Vpp to the gate of the switching element 41 causing the switching element 41 to be turned on. Thus, the GND is applied to the source line 40 via the common source line 42 and the switching element 41.

To write data or remove electrons from at least one of floating gates of the memory cells M11 to M23 via the drain thereof, the GND is applied to the byte select line 35 as well as to the source control line 44 to turn off the common source line control element 43. The Vpp is also applied to the word line (11 or 12) corresponding to the intended memory cell to turn on the byte select element (33 or 34). This causes the GND to be applied to the gate of the switching element 41 to turn off the switching element 41, thus interrupting the conduction between the source line 40 and the common source line 42. Note that the source line 40 will have a floating potential.

As such, to erase data, the switching element 41 is turned on to apply the GND to the source line 40. To write data, the switching element 41 is turned off to interrupt the conduction between the source line 40 and the common source line 42. To write data, the Vpp is applied to the drain of the intended memory cell via the bit line (any one of 21 to 23), and the potential thereof may also raise the potential of the source. In this case, the source line 40 to which the source is connected also has a raised potential. However, according to the present embodiment, the switching element 41 is turned off to interrupt the conduction between the source line 40 and the common source line 42, so that the potential of the common source line 42 is not affected by the rise in the potential of the source line 40.

The common source line 42, which is a common line for the whole of the EEPROM device 100 or a memory block unit of a certain size, has a large stray capacitance and is readily increased in potential. Furthermore, the common source line 42 is typically connected with a plurality of source lines (not shown) which are similar to the source line 40 shown in FIG. 1, thus allowing an increase in the potential of the common source line 42 to affect a wide range of, for example, the whole of the memory. That is, the conventional technique would cause the so-called disturbance phenomenon to occur. In this phenomenon, a rise in the potential of the common source line 42 affects a source line (not shown) to cause an increase in the potential of the source of an originally unintended memory cell that is connected to the source line, thus allowing data to be written onto the memory cell. In contrast, as described above, the present embodiment can prevent such a disturbance phenomenon. That is, when writing data, the switching element 41 is turned off to interrupt the conduction between the source line 40 and the common source line 42, thereby preventing the rise in the potential of the source line 40 from affecting the common source line 42.

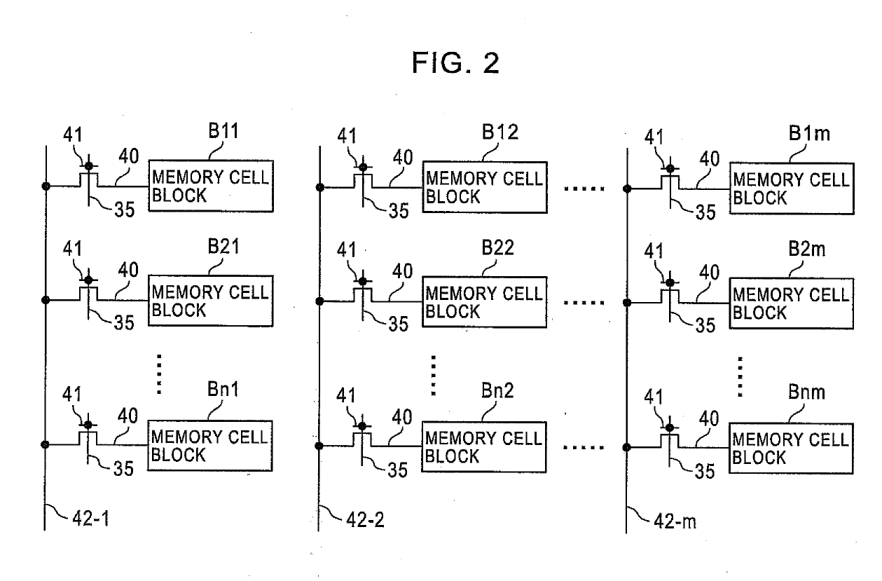

FIG. 2 is a block diagram illustrating the EEPROM device 100. The EEPROM device 100 includes memory cell blocks B11 to Bnm (n and m are integers) disposed in a matrix, and common source lines 42-1 to 42-m that are common to memory cell blocks in each column. The source line 40 of each of the memory cell blocks B11 to Bnm is connected to the common source line (42-1 to 42-m) in the corresponding respective column via the switching element (on/off switch element) 41. For example, the memory cell block B11 is configured as shown in FIG. 1, in which the common source line 42 shown in FIG. 1 corresponds to a common source line 42-1 shown in FIG. 2. The switching element 41 is an FET element and has the gate connected to the byte select line 35. The switching element 41 is turned on or off in response to the potential applied to the byte select line 35. Note that as required for at least one of the memory cell blocks B11 to Bnm, the source line 40 and the common source line 42 may be connected to each other without the intervention of the switching element (on/off switch element) 41.

As described above, the present embodiment is configured such that to write data, the switching element 41 is turned off to interrupt the conduction between the source line 40 and the common source line 42. Thus, even when the potential of the source line 40 of a memory block, which includes the memory cell to be erased, among the memory cell blocks B11 to Bnm has increased, the rise in the potential never affects the memory cell included in the other memory block.

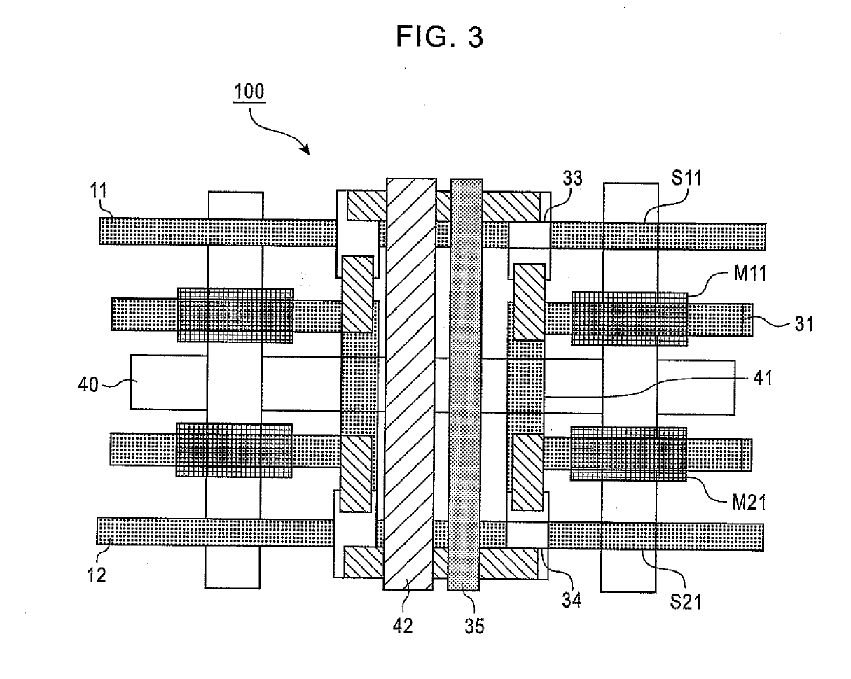

FIG. 3 is a layout diagram illustrating an example layout of the EEPROM device 100 according to the present embodiment. Note that FIG. 3 shows part of one memory block, but does not show the bit lines 21 to 23, the common source line control element 43, and the source control line 44. It can be realized that writing data onto any one of the memory cells M11 to M23 has no adverse effects on the common source line 42. From this point of view, as shown in FIGS. 1 and 3, the switching element 41 is preferably formed between the common source line 42 and the memory cells M11 and M21, which are disposed nearest to the common source line 42 in the row direction of the layout. Furthermore, as shown in FIGS. 1 and 3, the aforementioned effects can be attained only by providing one switching element (one FET element) for every 2 rows, thus never causing an increase in the size of the circuit.

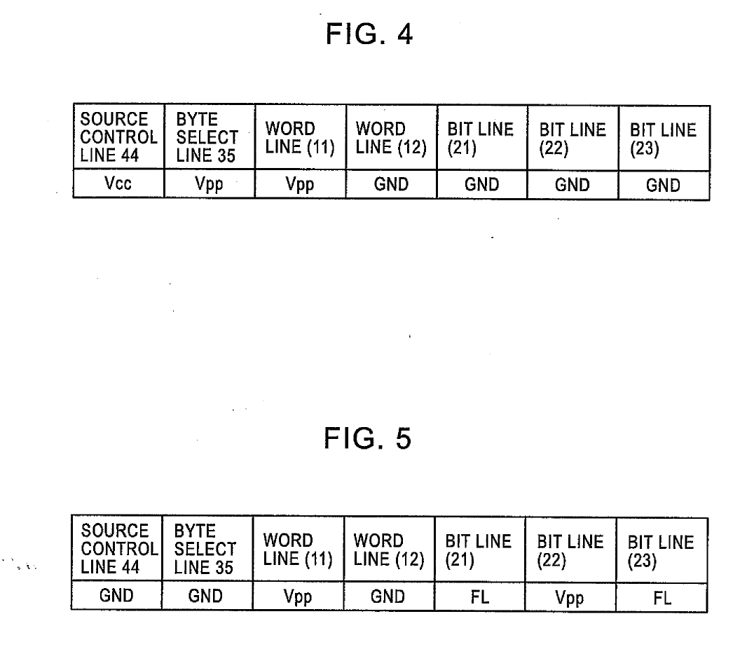

FIG. 4 is a table showing an example of a potential being set to erase data. Now, reference is made to FIGS. 1 and 3 to show an example of setting a potential when erasing data on the memory cells M11 to M13. In the table, the symbol “GND” refers to the ground potential, the “Vpp” refers to a high potential Vpp, the “Vcc” refers to a high potential Vcc, and the “FL” refers to a floating state.

The GND is applied to each of the bit lines 21 to 23. The Vpp is applied to the byte select line 35. The Vcc is applied to the source control line 44. Furthermore, the Vpp is applied to the word line 11 to turn on the byte select element 33 and each of the switch elements S11 to S13. This allows the GND applied to each of the bit lines 21 to 23 to be applied to the drain of each of the memory cells M11 to M13 via the switch elements S11 to S13. Furthermore, the Vpp applied to the byte select line 35 is applied to the gate of the switching element 41 or an FET element via the byte select element 33 to turn on the switching element 41. This allows the source line 40 and the common source line 42 to be electrically connected to each other.

On the other hand, the GND is applied to the source line 40 via the common source line control element 43 having been turned on by the Vcc being applied to the source control line 44 and the switching element 41 having been also turned on. Then, the GND is applied to the source of each of the memory cells M11 to M13. The Vpp applied to the byte select line 35 is applied to the control gate of each of the memory cells M11 to M13 via the byte select element 33. As such, to erase data, the GND is applied to the drain and source of each of the memory cells M11 to M13 (i.e., the substrate side), while the Vpp is applied to the control gate. This allows for injecting electrons into the floating gate of each of the memory cells M11 to M13 to thereby erase data thereon.

Note that the Vpp applied to the byte select line 35 is then also applied to the control gate of each of the memory cells M21 to M23; however, the GND applied to the word line 12 is applied to the gate of each of the switch elements S11 to S23 in an OFF state, which are paired with the memory cells M21 to M23. Thus, the drain of each of the memory cells M21 to M23 is floated causing no Vpp to be applied to their tunnel oxide film (not shown), so that no data is erased on the memory cells M21 to M23.

FIG. 5 is a table showing an example of setting a potential to write data. Now, reference will be made to FIGS. 1 and 4 to show an example of setting a potential to write data onto the memory cell M12. The symbols in the table refer to the same components as those of FIG. 4.

The Bit line 22 is supplied with the Vpp, allowing each of the bit lines 21 and 23 to be switched to a floating state. The byte select line 35 is supplied with the GND. The source control line 44 is also supplied with the GND. The word line 11 is then supplied with the Vpp to switch on the byte select element 33 and each of the switch elements S11 to S13. This allows the Vpp applied to the bit line 22 to be applied to the drain of the memory cell M12 via the switch element S12. The drain of each of the memory cells M11 and M13 is floated. Furthermore, the GND applied to the byte select line 35 is applied to the gate of the switching element 41 or an FET element via the byte select element 33 to switch off the switching element 41.

Since the switching element 41 is in an OFF state, the source line 40 and the common source line 42 are electrically isolated. This isolation leads to floating of the source line 40 and the source of each of the memory cells M11 to M13. Furthermore, the Vpp applied to the word line 11 is applied to the control gate of each of the memory cells M11 to M13 via the byte select element 33. As such, when writing data, the control gate of each of the memory cells M11 to M13 is switched to a floating state, and only the drain of the memory cell M12 is supplied with the Vpp. This allows for removing electrons only from the floating gate of the memory cell M12 via the drain thereof to write data only on the memory cell M12.

At this time, such a phenomenon may occur in which the Vpp applied to the drain of the memory cell 12 acts upon the source causing the potential of the source line 40 to rise as well. However, as described above, the switching element 41 is turned off, when writing data, to interrupt the conduction between the source line 40 and the common source line 42, so that even an increase in the potential of the source line 40 does not affect the potential of the common source line 42. Therefore, the so-called disturbance phenomenon can be prevented from occurring even in the presence of an increase in the potential of the source line 40. In this phenomenon, the increase would cause a rise even in the source potential of an originally unintended memory cell, which is connected to a source line (not shown) coupled to the common source line 42, thereby allowing data to be written onto that memory cell.

Note that while the GND applied to the byte select line 35 is then also applied to the control gate of each of the memory cells M21 to M23, the GND applied to the word line 12 is applied to the gate of each of the switch elements S11 to S23 in an OFF state, which are paired with the memory cells M21 to M23. Thus, the drain of each of the memory cells M21 to M23 is floated causing no data to be written onto the memory cells M21 to M23.

As described above, the EEPROM device according to the present embodiment includes a source line connected to the source of each of memory cells disposed in mutually adjacent rows, in which the source line is connected to a common source line via a switching element that is an FET element. When writing data on a memory cell, the switching element corresponding to the source line connected with the memory cell is turned off to interrupt the conduction between the source line and the common source line. This prevents even an increase in the potential of the source line caused by a write operation from having an effect on the common source line. It is therefore possible to avoid the so-called disturbance phenomenon in which data would be written also onto an originally unintended memory cell whose source is connected to another source line connected with the common source line. Furthermore, the aforementioned effect can be attained by providing only one switching element (FET element) in every two rows, thus without causing an increase in the size of the circuit.

### Second Embodiment

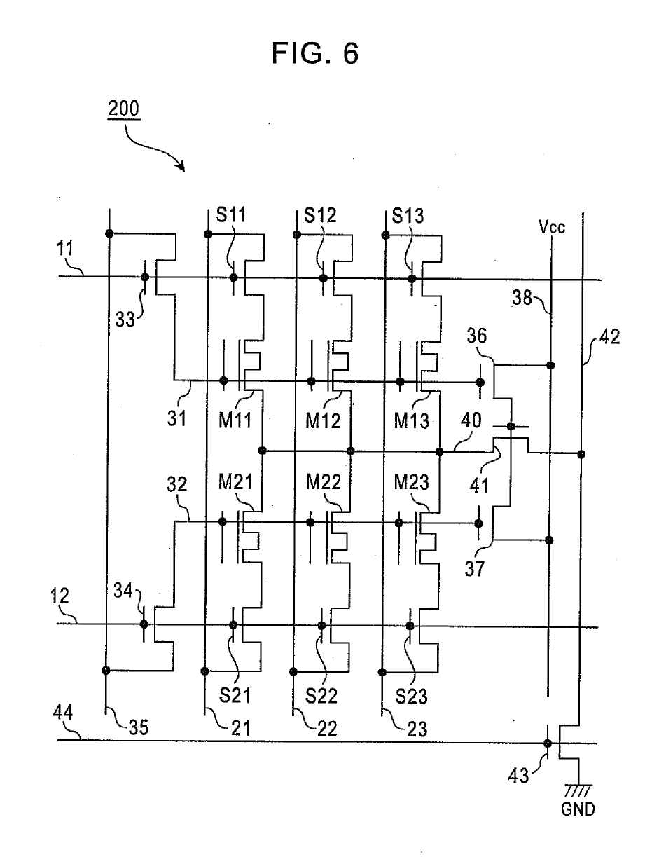

FIG. 6 is a circuit diagram illustrating an EEPROM device 200 according to the present embodiment. The EEPROM device 100 of the first embodiment is configured such that applying the Vpp to at least either one of the word lines 11 and 12 causes the potential applied to the byte select line 35 to be applied to all the gates of the memory cells M11 to M23. In contrast, the EEPROM device 200 of the second embodiment differs from the device 100 in that the gate of each of the memory cells M11 to M13 is electrically independent of the gate of each of the memory cells M21 to M23. A description will now be made mainly to those points that are not implemented in the first embodiment.

The EEPROM device 200 further includes byte source elements 36 and 37 and a power supply line 38. The drain of the byte source element 36 or an FET element is connected to the power supply line 38, the source is connected to the gate of the switching element 41 or an FET element as its control terminal, and the gate is connected to the gate line 31. Furthermore, the drain of the byte source element 37 or an FET element is connected to the power supply line 38, the source is connected to the gate of the switching element 41 or an FET element, and the gate is connected to the gate line 32. The power supply line 38 is supplied with a high potential Vcc. The Vcc is a potential lower than the Vpp that is applied to the memory cells M11 to M23.

One end of the gate line 31 is connected to the byte select line 35 via the byte select element 33, and the other end is connected to the gate of the byte source element 36 or an FET element. Furthermore, one end of the gate line 32 is connected to the byte select line 35 via the byte select element 34, and the other end is connected to the gate of the byte source element 37 or an FET element. The gate line 31 is connected with the gate of each of the memory cells M11 to M13, while the gate line 32 is connected with the gate of each of the memory cells M21 to M23 in the same manner as in the first embodiment.

A description will now be made to the operation to erase data on the memory cells M11 to M13. Each of the bit lines 21 to 23 is supplied with the GND. The byte select line 35 is supplied with the Vpp. Furthermore, the source control line 44 is supplied with the Vcc. The word line 11 is supplied with the Vpp serving also as a control signal to turn on or off the switching element 41, thereby placing the byte select element 33 and each of the switch elements S11 to S13 into an ON state. Since the gate line 31 and the gate line 32 are not connected to each other and the word line 12 is supplied with the GND, the byte select element 34 and each of the switch elements S21 to S23 are in an OFF state.

The GND applied to each of the bit lines 21 to 23 is applied to the drain of each of the memory cells M11 to M13 via the switch elements S11 to S13. On the other hand, the Vpp applied to the byte select line 35 is applied to the gate of the byte source element 36 or an FET element via the byte select element 33. The byte source element 36 is switched on, and thus the Vcc applied to the power supply line 38 is applied to the gate of the switching element 41 or an FET element, causing the switching element 41 to be turned on. This allows for electrically connecting between the source line 40 and the common source line 42.

Furthermore, the GND is applied to the source line 40 via the common source line control element 43 having been turned on by the Vcc being applied to the source control line 44 and the switching element 41 having been also turned on. Then, the GND is applied to the source of each of the memory cells M11 to M13. Furthermore, the Vpp applied to the byte select line 35 is applied to the control gate of each of the memory cells M11 to M13 via the byte select element 33. As such, to erase data, the GND is applied to the drain and source of each of the memory cells M11 to M13 (i.e., the substrate side), while the Vpp is applied to the control gate. This allows for injecting electrons into the floating gate of each of the memory cells M11 to M13 to thereby erase data thereon.

A description will now be made to the operation to write data on the memory cell M12. The bit line 22 is supplied with the Vpp, while each of the bit lines 21 and 23 is in a floating state. The Byte select line 35 is supplied with the GND. The source control line 44 is also supplied with the GND. The power supply line 38 is supplied with the Vcc. Then, the word line 11 is supplied with the Vpp to turn on the byte select element 33 and each of the switch elements S11 to S13. Since the gate line 31 and the gate line 32 are not connected to each other and the word line 12 is supplied with the GND, the byte select element 34 and each of the switch elements S21 to S23 are in an OFF state.

The Vpp applied to the bit line 22 is applied to the drain of the memory cell M12 via the switch element S12. The drain of each of the memory cells M11 and M13 is switched to a floating state. The GND applied to the byte select line 35 is also applied to the gate of the byte source element 36 or an FET element via the byte select element 33. Since the byte source element 36 is turned off, the Vcc applied to the power supply line 38 is not applied to the gate of the switching element 41 or an FET element, allowing the switching element 41 to be also turned off. This causes the source line 40 and the common source line 42 to be electrically disconnected from each other, thus preventing even an increase in the potential of the source line 40 from having an effect on the common source line 42. That is, the disturbance does not occur as in the first embodiment.

As described above, the EEPROM device 200 according to the present embodiment can prevent the disturbance phenomenon as with the first embodiment. Furthermore, the device 200 is configured such that each gate of adjacent memory cells is electrically independent of each other, thus making it possible to erase or write data with improved stability.

Furthermore, a power supply line that is provided for supplying power to the gate of a switching element or an FET element can apply an inherent high potential to the gate of the switching element. This inherent high potential can be made lower than a high potential applied to the memory cell, thereby allowing for employing, as the switching element, a high-drive-power LV transistor element with a thin gate oxide film. It is thus possible to minimize the reduction in the current flowing through the memory cell.

This application is based on Japanese Patent Application No. 2009-146018 which is herein incorporated by reference.

What is claimed is:

1. An EEPROM device comprising:
a plurality of memory cell FETs;
an individual source line and a bit line for supplying a potential difference between a source and a drain of the memory cell FET;
a gate line connected to a gate of the memory cell FET;
a byte select line for supplying a write/erase potential to the gate line; and
an on/off switch element for selectively connecting between the individual source line and a common source line in response to a control signal supplied via its control terminal.

2. The EEPROM device according to claim 1, wherein:
the on/off switch element is an FET element having a gate as the control terminal; and
the FET element has a drain connected to the individual source line and a source connected to the common source line.

3. The EEPROM device according to claim 2, wherein the FET element has a gate connected to the gate line.

4. The EEPROM device according to claim 2, further comprising a power supply line connected to the gate of the FET element.

5. The EEPROM device according to claim 1, wherein:
the plurality of memory cell FETs are disposed to form mutually adjacent and opposing rows and include first and second groups of memory cell FETs connected to one of the individual source lines; and
the on/off switch element is formed between the common source line and the memory cell FET, the memory cell FET being disposed nearest to the common source line in the one individual source line.

6. An EEPROM device comprising:
a plurality of memory cell blocks which each include a plurality of memory cell FETs and are disposed in a matrix;
a supply source line for supplying a source potential to an individual source line of each of the memory cell blocks; and
an on/off switch element for selectively connecting between the individual source line and the supply source line in response to a control signal supplied via its control terminal.
